(19) United States
(12) Patent Application Publication
(10) Pub. No.: US 2013/0112254 A1
(43) Pub. Date: May 9, 2013

(54) PHOTOVOLTAIC CELL

(71) Applicant: BASF SE, Ludwigshafen (DE)

(72) Inventors: CESARE LORENZETTI, GROTTAMMARE (AP) (IT); MARCELLO VITALE, CASTEL D'AIANO (BO) (IT)

(73) Assignee: BASF SE, LUDWIGSHAFEN (DE)

(21) Appl. No.: 13/688,393

(22) Filed: Nov. 29, 2012

Related U.S. Application Data
(63) Continuation of application No. 12/226,181, filed on Mar. 20, 2009.

(30) Foreign Application Priority Data
Apr. 13, 2006 (EP) 06112590.2

(51) Int. Cl. H01L 31/0352; H01L 31/18

(52) U.S. Cl. CPC H01L 31/035209; H01L 31/18; Y10S 977/773; Y10S 977/954; B82Y 20/00
USPC 136/255; 438/63; 977/773; 977/954

(57) ABSTRACT

A photovoltaic cell of high efficiency may be obtained using metallic nanoparticles or nanostructures as the main light absorbing element in the photosensitive layer of the cell, which absorb the light through a surface plasmon or polaron mechanism. The cell comprises at least one photosensitive layer containing nanoparticles or nanostructures each between a n-doped and a p-doped charge transport layer, characterized in that
the nanoparticles or nanostructures are the main light absorbing element in the photosensitive layer,
the nanoparticles or nanostructures have metallic conductivity and absorb near infrared, visible and/or ultraviolet light through a surface plasmon or polaron mechanism, and
the nanoparticles or nanostructures have at least one of their dimensions of size between 0.1 and 500 nm.

By exploiting the combination of electronic and size parameters, intense optical absorption at any wavelength within the solar spectrum (about 2500 and 300 nm) can be obtained and the whole range of the solar spectrum may be used.

This application is a continuation of U.S. application Ser. No. 12/226,181, pending, which is a national stage of international app. No. PCT/EP2007/053454, filed Apr. 10, 2007, the contents of which applications are incorporated by reference.

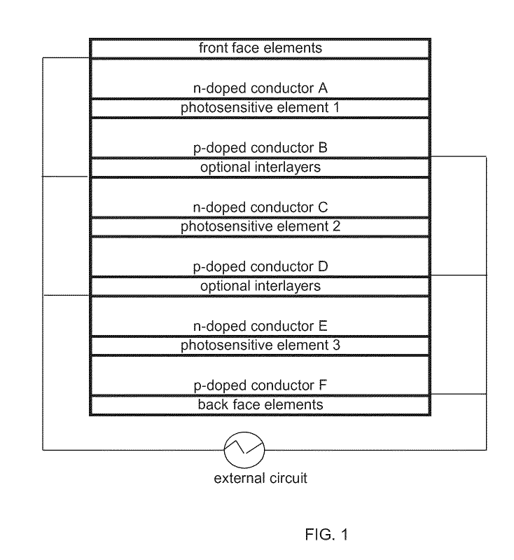

The present invention concerns a novel photovoltaic cell design which is able to generate electrical power from the whole solar spectrum, from near infrared to ultraviolet light. Such device is highly efficient at transforming each absorbed solar photon in electrical current. It achieves such objective by utilizing nanoparticles or nanostructures as the main light-absorbing elements inside the i-layer of an n-i-p or p-i-n, multistack photovoltaic cell configuration (example: see FIG. 1, showing a 3 photoconversion elements cell of the invention).

### STATE OF THE ART

The known processes of converting sunlight into electricity still require improvements in order to allow for economical exploitation on a large scale. Efficiency shortfalls are slowing down substitution of renewable solar energy for the fossil fuels currently employed to produce much of the world's electrical power. A brief discussion of the main type of photovoltaic cells currently available can be found at http://www.eere.energy.gov/solar/solar_cell_structures.html

A series of problems affect photovoltaic conversion efficiency:
the photoelectric elements are not sensitive to all the wavelengths at which the sun emits energy (insufficient spectral coverage)
not all of the solar photons falling on the photocell's surface are absorbed by it, even at wavelengths to which the photoelectric elements are sensitive (insufficient absorption cross section)
not all the absorbed photons result in the formation of a physically-separated electron-hole pair (unsuitable electronic transition)
not all the electrons and all the holes travel in the same direction, thereby resulting in a lower net current (random electronic walk)
some of the electrons and holes either recombine or are otherwise blocked by defects or traps in the conducting medium before arriving to an external circuits and becoming usable (competing processes).

Critical step generally is the absorption of light and separation of charges in the main photosensitive layer (usually the so-called i-layer). EP-A-729190 describes a cell wherein the i-layer is formed by plasma vapour deposition of silicon microcristallites from monosilane between n- and p-doped silicon film layer.

WO 98/04006 discloses the use of Si-, Ge- or CdTe-clusters of varying sizes in a photovoltaic cell in order to exploit their different absorption spectra. Similarly, GB-A-2341002 proposes the use inter alia of 5 nm sized metal clusters to improve the spectral sensitivity of the Zn-phthalocyanine chromophor in a photovoltaic cell.

EP-A-1180802 describes a photovoltaic cell using oriented semiconducting spheres as the photosensitive element allowing for surface plasmons. The excited plasmons are on the outside of the pn junction-formed electric field, where such field is vanishing, and the overall cell design is complicated.

Ru-C1-2 222 846 describes a photovoltaic cell using nanoparticles possessing surface plasmons in order to improve charge separation and transport within the n-type semiconductor layer of an n-p cell design.

Nanoparticles or nanostructures are known to interact with visible light in a different manner than macroscopic pieces of the same material. In particular, metallic nanostructures present surface plasmon or polaron resonance absorption, manifesting itself in a very high absorption cross section at wavelengths which depend on both material's electronic properties and particle or structure size (see, for example, Electrochim. Acta 2001, 46, 1967-1971). Tian et al., J. Am. Chem. Soc. 2005, 127, 7632-7637, describe a photovoltaic cell using gold particles of less than 50 nm size in TiO₂ as a photoanode in contact with a donor solution.

### DETAILS OF THE INVENTION

It has now been found that a photovoltaic cell of high efficiency may be obtained using metallic nanoparticles or nanostructures, which absorb the light through a surface plasmon or polaron mechanism, as the main light absorbing element in the photosensitive layer of the cell. Thus, the present invention pertains to a photovoltaic cell comprising at least one photosensitive layer containing nanoparticles or nanostructures, and additionally comprising at least one n-doped charge transport layer and at least one p-doped charge transport layer per each photosensitive layer, placed on each side of said photosensitive layer, characterized in that
the nanoparticles or nanostructures are the main light absorbing element in the photosensitive layer,
the nanoparticles or nanostructures have metallic conductivity and absorb near infrared, visible and/or ultraviolet light through a surface plasmon or polaron mechanism, and
the nanoparticles or nanostructures have at least one of their dimensions of size between 0.1 and 500 nm, and
at least 50% by weight of said nanoparticles or nanostructures, in a preferred embodiment more than 70%, especially more than 90% by weight, in all layers (photosensitive layer, n-doped charge transport layer, p-doped charge transport layer) are contained in said photosensitive layer.

By exploiting the combination of electronic and size parameters, intense optical absorption at any wavelength within the solar spectrum (anywhere between about 2500 and 300 nm) can be obtained. Thus, by employing nanoparticles or nanostructures, especially a combination of such particles or structures of different compositions and/or sizes, showing suitable plasmon or polaron resonance absorption, the whole range of the solar spectrum may be used.

The photovoltaic cell may absorb substantially all light of the solar spectrum, i.e., for example, 50% or more, preferably 70% or more, especially 90% or more, of the radiation energy between 1800 and 300 nm. The cell preferably comprises between 1 and 100 main photosensitive layers. Nanoparticles or nanostructures in a main photosensitive layer usually have at least one of their dimensions of size between 0.1 and 500 nm.

When a photon is absorbed by such nanoparticles or nanostructures, it creates an electron-hole pair necessarily at or very near the surface of the very small particles or structures. If the nanoparticles or nanostructure are incorporated in a matrix where positive or negative charges can travel with relative ease, i.e. conductive or semiconductive, such electrons and holes can be transferred easily into the surrounding matrix, maximizing the photoconversion efficiency of the device.

Such transfer of the charge carriers to the surrounding medium can be driven and directed, electrons in one direction, holes in the opposite direction, by the electric field obtained by the presence, adjacent to the photosensitive nanoparticles or nanostructures, of an n-doped and a p-doped conducting or semiconducting layer (as in the common n-i-p/p-i-n design). Thus, the loss of efficiency due to charge recombinations and charge dissipations associated with charge transport through random walk may be minimized and the photoconversion efficiency of the device maximized.

Through such charge transport layers, the charge carriers can finally travel to suitably placed electrodes and finally to an external circuit to produce useful work. Overall, by the use of such a device, open-circuit voltage, short-circuit photocurrent, low-illuminance open-circuit voltage and leak current can all be optimized.

It has been found that particles of a certain size and coimposition are capable of absorbing near infrared, visible and/or ultraviolet light generally through a surface plasmon or polaron resonance mechanism, and that a photovoltaic current thus may be observed on contacting at least one main photosensitive layer made of nanoparticles or nanostructures absorbing near infrared, visible or ultraviolet light through a surface plasmon or polaron mechanism, with at least one n-doped and at least one p-doped charge transport layer per each main photosensitive layer, placed on each side of said main photosensitive layer.

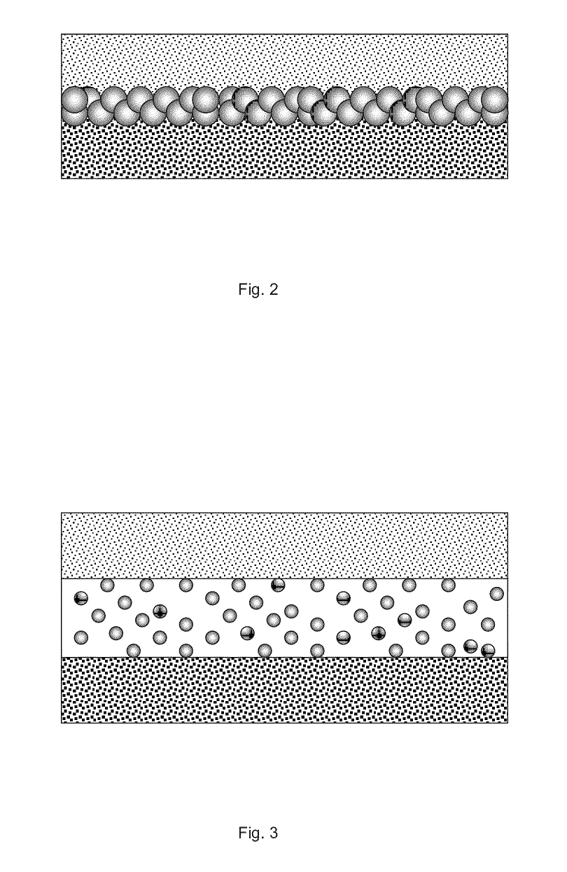

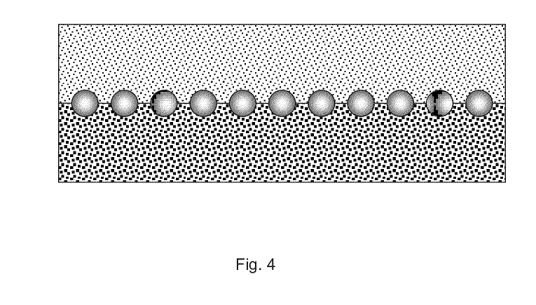

The nanoparticles or nanostructures as the main light absorbing element in the photosensitive layer usually absorb more than 50% of the radiation absorbed by the photosensitive layer, or more preferably by the whole cell, at each wavelength. The nanoparticles or nanostructures as the main light absorbing element in the photosensitive layer usually absorb more than 50%, preferably more than 80%, especially more than 90%, of the total radiation from the range 400-800 nm, especially 300-2500 nm, absorbed by the photosensitive layer, or more preferably by the whole cell. The photovoltaic cell of the invention usually does not contain an organic dye or pigment. In general, the present nanoparticles or nanostructures make up a major part (as shown, for example, in FIG. 3) or most or all of the photosensitive layer (see, e.g., FIGS. 2 and 4 further below).

The nanoparticles can be of any material of appropriate electrical properties, organic or inorganic in nature. Preferably the nanoparticles are made of inorganic materials such as metals or the combinations of one or more metallic element with one or more elements of main groups III through VII. Commonly used doping technologies can be employed to tune the electronic properties of such materials, creating local excess of positive or negative charges. Included in the scope of this invention are composite particle structures such as core-shell structures, multiple layer tubes or plates, in which each particle is formed by two or more materials of different electrical properties (see for example WO2004077453). In a preferred embodiment, the nanoparticles or nanostructures in the photosensitive layer are made of a material selected from noble metals (such as Ag, Au, Cu, Pt, Pd; especially Cu, Ag, Au), conductive oxides such as non-stoichiometric oxides (e.g. those of Sn, In, As, Sb, Zn, W, Nb, Ga and V, their combinations and/or doped analogues thereof), bronzes (such as doped oxides of W, Nb, V etc.), nitrides, sulfides, selenides, borides, silicides or the combinations of one or more metallic element with one or more elements of main groups III through VII.

Materials that have been shown to possess especially useful properties in this regard include, but are not limited to, metals such as Cu, Ag and Au, metal oxides (even non stoichiometric) such as those of transition metals, e.g. W, Zn, Sn, In etc., as well as corresponding nitrides, sulfides, selenides, silicides and borides. Also preferred is an alloy of a metal with copper, silver and/or gold containing at least 50 atom-% of Cu, Ag, Au, or an alloy from the systems Cu/Ag, Cu/Au, Ag/Au, Cu/Ag/Au.

The nanoparticles of the invention can be, e.g., spheres, rods, cubes, hollow cylinders, flakes or platelets. Nanostructures include homogeneous films, “mountain and valley” structures, cusps, domes and dimples and any other rough structure that leads to quantum confinement effects.

Particles or structures presenting such properties usually have at least one, preferably all, of their dimensions of a size comprised between 0.1 and 500 nm; more preferred size ranges are 0.1 to 200, especially about 1 to 80 nm. For each particular material, particles of different sizes have different optical absorption spectra.

The present invention thus relates to a photovoltaic cell comprised of at least one main photosensitive layer containing nanoparticles or nanostructures, especially of a conductive or semiconductive metal or metal compound as mentioned above. Bulk conductivity of the nanoparticle or nanostructure material usually will be such that a specific resistance (resistivity) at the temperature of operation of lower than 100, preferably lower than 1, more preferably lower than 0.1, and especially lower than 0.01 Ωcm is realized by at least 60%, or preferably at least 80% by weight of the nanoparticles or nanostructures of the invention contained in the photosensitive layer(s). In general, electrical conductivity of the present nanoparticle or nanostructure material decreases with temperature. Temperature of operation of the photovoltaic cell of the invention generally is in the range from about −50 to about +150° C., especially between about −20 to about 100° C., in particular in the ambient range.

The present invention allows for a low overall size of the element, requiring only thin layers of each function and is suitable for flexible photovoltaics. Thus, the present invention further pertains to a flexible photovoltaic cell, wherein the layers are positioned on a polymer film substrate, especially wherein at least one, preferably all but one or all, of the cover layers (front and/or backface elements) and, where present, intermediate layers is a transparent polymer film of about 5 to 150 μm thickness and/or at least one electrode comprises an organic conducting material. The present invention also allows for flexible photovoltaics by allowing for the charge transport layers to be made of amorphous or quasi-amorphous silicon, which can be evaporated onto a flexible plastic substrate as disclosed by U.S. Pat. No. 4,663,828 and U.S. Pat. No. 4,663,829.

Within a main photosensitive layer, it is possible to exclusively use nanoparticles or nanostructures of same material and size, a combination of nanoparticles or nanostructures of different size of the same material, or a combination of nanoparticles or nanostructures of the same or different size of different materials. Multiple layers, each corresponding to one of the above compositions, can be used to capture and convert light of different wavelengths, or to ensure that all available photons of each wavelength are captured and converted. In particular, each of such multiple layers can constitute the main photosensitive layer i of an n-i-p or p-i-n structure, many of which, from 1 to 100, can be stacked together in a series as shown schematically in FIG. 1.

The main photosensitive layers may be continuous (e.g. as in FIG. 2), may present the nanoparticles or nanostructures dispersed in a semiconducting or conducting matrix, such as TiO₂ or undoped Si (e.g. as in FIG. 3), or may present isolated nanoparticles nanostructures which would not completely separate the adjacent n- and p-doped layers (e.g. as shown in FIG. 4).

Such a photovoltaic cell also comprises at least one n-doped and at least one p-doped charge transport layer per each main photosensitive layer, placed on opposite sides of said photosensitive layer. The composition and size of such charge transport layers are already well established in the art. Such charge transport layers are usually transparent to the wavelengths of light to be captured and converted further away from the cell's front surface, but can also act as secondary photosensitive elements; thus the layer(s) containing the present nanoparticles or nanostructures is/are to be understood, and in some cases recalled, as the main photosensitive layer(s). The material of the charge transport layers may be organic, inorganic or hybrid. In particular, in one preferred embodiment, the charge transport layers are made of differently doped amorphous, semi-amorphous or microcrystalline or crystalline (wafer) silicon.

Useful examples of the p-type semiconductor layers employed in the photovoltaic device include a thin film of p-type amorphous silicon, amorphous silicon carbide, microcrystalline silicon, microcrystalline silicon carbide or carbon-containing microcrystalline silicon, a multilayer film of amorphous silicon carbides having different carbon contents, and a multilayer film of amorphous silicon and amorphous carbon. A thin film of p-type microcrystalline silicon, microcrystalline silicon carbide or carbon-containing microcrystalline silicon is more preferred.

In the present invention, decoupling the light absorption function from the charge transport function, may further allow for the use of wide-gap semiconductors including, for example, TiO₂, ZnO₂ and SnO₂, suitably doped n- or p-, to constitute the charge-transport elements.

They are not currently useful because of their poor light absorption properties; indeed, In-doped SnO₂ (aka ITO) is used widely as completely transparent charge transport material in general electronic component manufacturing.

Effectively usable examples of the n-type semiconductor layers employed in the photovoltaic device include a thin n-type microcrystalline silicon film, a thin carbon-containing microcrystalline silicon film, a thin microcrystalline silicon carbide film, a thin amorphous silicon film, a thin amorphous silicon carbide film, and a thin amorphous silicon germanium film. Also usable are n-type crystalline Si wafers.

As a process for the formation of the p-type semiconductor layers, PVD, plasma CVD, PECVD or photo-assisted CVD can be used. As raw material for such a process, silane, disilane or trisilane is employed as a silicon compound. Further, as a dopant for imparting p-type conductivity, diborane, trimethylboron, trifluoroboron or the like is preferred. Moreover, as a carbon-containing compound, a saturated hydrocarbon such as methane or ethane, an unsaturated hydrocarbon such as ethylene or acetylene, or an alkylsilane such as a monomethylsilane or dimethylsilane is used. Such a mixed gas optionally may be diluted with an inert gas such as helium or argon and/or with hydrogen.

The n-type semiconductor layers can be formed by mixing a compound containing a group V element of the Periodic Table (i.e. main group V, also recalled as nitrogen group), such as phosphine or arsine, and hydrogen with a raw material chosen as required depending on the target semiconductor from compounds containing silicon in their molecules, compounds containing germanium in their molecules, such as germane or silylgermane, hydrocarbon gases and the like, and applying plasma CVD or photo-assisted CVD. Further, dilution of the feed gas with an inert gas such as helium or argon is possible.

As conditions for the formation of the p-type and n-type semiconductor layers, the film thickness usually ranges from 2 to 100 nm, the depositing temperature usually ranges from 50 to 400° C., and the forming pressure usually ranges from 0.01 to 5 Torr. Upon formation by RF plasma CVD, the RF power advantageously should be in the range of from 0.01 mW/cm² to 10 W/cm².

Compounds useful in the above-described feed gas are as follows: Compounds containing silicon in the molecule include silicon hydrides such as monosilane, disilane and trisilane; alkyl-substituted silicon hydrides such as monomethylsilane, dimethylsilane, trimethylsilane, tetramethylsilane, ethylsilane and diethylsilane; silicon hydrides containing one or more radically polymerizable, unsaturated hydrocarbon groups such as vinylsilane, di vinylsilane, trivinylsilane, vinyl-disilane, di vinyldisilane, propenylsilane and ethenylsilane; and fluorinated silicons obtained by either partly or wholly substituting the hydrogen atoms of these silicon hydrides with fluorine atoms. Useful specific examples of the hydrocarbon gas include methane, ethane, propane, ethylene, propylene and acetylene.

In both the n-type and p-type semiconductor layers, conducting or semiconducting nanoparticles may also be added, especially to improve their charge transport characteristics, in minor amounts as described in RU-C1-2 222 846.

A schematic example of the overall photovoltaic cell structure object of the present invention is shown in FIG. 1. Therein, the main photosensitive layers 1, 2, and 3 may be the same or different, as may the n-doped layers A, C, and E and the p-doped layers B, D, and F. The device may contain additional layers, e.g. an electrode layer on the far side of each n- or p-doped conductor layer relative to the photosensitive layer, an insulating layer between the separate photoconversion elements, or an interlayer between a semiconducting charge transport layer and a main photosensitive layer or an electrode. The term electrode means a translucent electrode or metal electrode, usually chosen so as to allow for light to pass that is to be captured and converted further from the light-impinging side than that particular electrode. Effectively usable examples of the material for the translucent electrodes include metal oxides such as tin oxide, indium oxide, zinc oxide and their combinations, translucent metals and the like. Metal electrodes can be made of aluminum, chromium, copper, silver, gold, platinum and their alloys, also with other elements such as nickel and iron.

The main photosensitive layers may be continuous (e.g. as in FIG. 2), may present the nanoparticles or nanostructures dispersed in a semiconducting or conducting matrix, such as TiO₂ or undoped Si (e.g. as in FIG. 3), or may present isolated nanoparticles nanostructures which would not completely separate the adjacent n- and p-doped layers (e.g. as shown in FIG. 4).

Between each set comprised of at least one n-doped charge transport layer, a (main) photosensitive layer and at least one p-doped charge transport layer, an insulator or conductor layer may be placed (see FIG. 1: optional interlayers), according to state-of-the-art procedures. Front elements, such as antireflection or antiscratch layers, and back elements, such as backreflecting layers or dump electrodes, might also be employed according to the state of the art. Equally, any type of suitable substrate can be employed, insofar as such substrate has a thickness and surface configurations sufficient to allow the solar cell to retain its shape under the conditions of use. Useful substrate materials include glass or quartz sheets, ceramic sheets such as alumina, boron nitride or silicon sheets, metal sheets and metal-coated ceramic or polymer sheets, and polymer sheets or films such as those of the following polymers:

1. Polymers of monoolefins and diolefins, for example polypropylene, polyisobutylene, polybut-1-ene, poly-4-methylpent-1-ene, polyvinylcyclohexane, polyisoprene or polybutadiene, as well as polymers of cycloolefins, for instance of cyclopentene or norbornene, polyethylene (which optionally can be crosslinked), for example high density polyethylene (HDPE), high density and high molecular weight polyethylene (HDPE-HMW), high density and ultrahigh molecular weight polyethylene (HDPE-UHMW), medium density polyethylene (MDPE), low density polyethylene (LDPE), linear low density polyethylene (LLDPE), (VLDPE) and (ULDPE).

Polyolefins, i.e. the polymers of monoolefins exemplified in the preceding paragraph, preferably polyethylene and polypropylene, can be prepared by different, and especially by the following, methods:
a) radical polymerisation (normally under high pressure and at elevated temperature).
b) catalytic polymerisation using a catalyst that normally contains one or more than one metal of groups IVb, Vb, VIb or VIII of the Periodic Table. These metals usually have one or more than one ligand, typically oxides, halides, alcoholates, esters, ethers, amines, alkyls, alkenyls and/or aryls that may be either π- or σ-coordinated. These metal complexes may be in the free form or fixed on substrates, typically on activated magnesium chloride, titanium(III) chloride, alumina or silicon oxide. These catalysts may be soluble or insoluble in the polymerisation medium. The catalysts can be used by themselves in the polymerisation or further activators may be used, typically metal alkyls, metal hydrides, metal alkyl halides, metal alkyl oxides or metal alkyloxanes, said metals being elements of groups Ia, IIa and/or IIIa of the Periodic Table. The activators may be modified conveniently with further ester, ether, amine or silyl ether groups. These catalyst systems are usually termed Phillips, Standard Oil Indiana, Ziegler (-Natta), TNZ (DuPont), metallocene or single site catalysts (SSC).

2. Mixtures of the polymers mentioned under 1), for example mixtures of polypropylene with polyisobutylene, polypropylene with polyethylene (for example PP/HDPE, PP/LDPE) and mixtures of different types of polyethylene (for example LDPE/HDPE).

3. Copolymers of monoolefins and diolefins with each other or with other vinyl monomers, for example ethylene/propylene copolymers, linear low density polyethylene (LLDPE) and mixtures thereof with low density polyethylene (LDPE), propylene/but-1-ene copolymers, propylene/isobutylene copolymers, ethylene/but-1-ene copolymers, ethylene/hexene copolymers, ethylene/methylpentene copolymers, ethylene/heptene copolymers, ethylene/octene copolymers, ethylene/vinylcyclohexane copolymers, ethylene/cycloolefin copolymers (e.g. ethylene/norbornene like COC), ethylene/1-olefins copolymers, where the 1-olefin is generated in-situ; propylene/butadiene copolymers, isobutylene/isoprene copolymers, ethylene/vinylcyclohexene copolymers, ethylene/alkyl acrylate copolymers, ethylene/alkyl methacrylate copolymers, ethylene/vinyl acetate copolymers or ethylene/acrylic acid copolymers and their salts (ionomers) as well as terpolymers of ethylene with propylene and a diene such as hexadiene, dicyclopentadiene or ethylidene-norbornene; and mixtures of such copolymers with one another and with polymers mentioned in 1) above, for example polypropylene/ethylenepropylene copolymers, LDPE/ethylene-vinyl acetate copolymers (EVA), LDPE/ethylene-acrylic acid copolymers (EAA), LLDPE/EVA, LLDPE/EAA and alternating or random polyalkylene/carbon monoxide copolymers and mixtures thereof with other polymers, for example polyamides.

4. Aromatic homopolymers and copolymers derived from vinyl aromatic monomers including styrene, α-methylstyrene, all isomers of vinyl toluene, especially p-vinyltoluene, all isomers of ethyl styrene, propyl styrene, vinyl biphenyl, vinyl naphthalene, and vinyl anthracene, and mixtures thereof. Homopolymers and copolymers may have any stereostructure including syndiotactic, isotactic, hemi-isotactic or atactic; where atactic polymers are preferred. Stereoblock polymers are also included.

5. Copolymers including aforementioned vinyl aromatic monomers and comonomers selected from ethylene, propylene, dienes, nitriles, acids, maleic anhydrides, maleimides, vinyl acetate and vinyl chloride or acrylic derivatives and mixtures thereof, for example styrene/butadiene, styrene/acrylonitrile, styrene/ethylene (interpolymers), styrene/alkyl methacrylate, styrene/butadiene/alkyl acrylate, styrene/butadiene/alkyl methacrylate, styrene/maleic anhydride, styrene/acrylonitrile/methyl acrylate; mixtures of high impact strength of styrene copolymers and another polymer, for example a polyacrylate, a diene polymer or an ethylene/propylene/diene terpolymer; and block copolymers of styrene such as styrene/butadiene/styrene, styrene/isoprene/styrene, styrene/ethylene/butylene/styrene or styrene/ethylene/propylene/styrene.

6. Hydrogenated aromatic polymers derived from hydrogenation of polymers mentioned under 4.), especially including polycyclohexylethylene (PCHE) prepared by hydrogenating atactic polystyrene, often referred to as polyvinylcyclohexane (PVCH).

6a. Hydrogenated aromatic polymers derived from hydrogenation of polymers mentioned under 5.).

Homopolymers and copolymers may have any stereostructure including syndiotactic, isotactic, hemi-isotactic or atactic; where atactic polymers are preferred. Stereoblock polymers are also included.

7. Graft copolymers of vinyl aromatic monomers such as styrene or α-methylstyrene, for example styrene on polybutadiene, styrene on polybutadiene-styrene or polybutadiene-acrylonitrile copolymers; styrene and acrylonitrile (or methacrylonitrile) on polybutadiene; styrene, acrylonitrile and methyl methacrylate on polybutadiene; styrene and maleic anhydride on polybutadiene; styrene, acrylonitrile and maleic anhydride or maleimide on polybutadiene; styrene and maleimide on polybutadiene; styrene and alkyl acrylates or methacrylates on polybutadiene; styrene and acrylonitrile on ethylene/propylene/diene terpolymers; styrene and acrylonitrile on polyalkyl acrylates or polyalkyl methacrylates, styrene and acrylonitrile on acrylate/butadiene copolymers, as well as mixtures thereof with the copolymers listed under 6), for example the copolymer mixtures known as ABS, MBS, ASA or AES polymers.

8. Halogen-containing polymers such as polychloroprene, chlorinated rubbers, chlorinated and brominated copolymer of isobutylene-isoprene (halobutyl rubber), chlorinated or sulfochlorinated polyethylene, copolymers of ethylene and chlorinated ethylene, epichlorohydrin homo- and copolymers, especially polymers of halogen-containing vinyl compounds, for example polyvinyl chloride, polyvinylidene chloride, polyvinyl fluoride, polyvinylidene fluoride, as well as copolymers thereof such as vinyl chloride/vinylidene chloride, vinyl chloride/vinyl acetate or vinylidene chloride/vinyl acetate copolymers.

9. Polymers derived from α,β-unsaturated acids and derivatives thereof such as polyacrylates and polymethacrylates; polymethyl methacrylates, polyacrylamides and polyacrylonitriles, impact-modified with butyl acrylate.

10. Copolymers of the monomers mentioned under 9) with each other or with other unsaturated monomers, for example acrylonitrile/butadiene copolymers, acrylonitrile/alkyl acrylate copolymers, acrylonitrile/alkoxyalkyl acrylate or acrylonitrile/vinyl halide copolymers or acrylonitrile/alkyl methacrylate/butadiene terpolymers.

11. Polymers derived from unsaturated alcohols and amines or the acyl derivatives or acetals thereof, for example polyvinyl alcohol, polyvinyl acetate, polyvinyl stearate, polyvinyl benzoate, polyvinyl maleate, polyvinyl butyral, polyallyl phthalate or polyallyl melamine; as well as their copolymers with olefins mentioned in 1) above.

12. Homopolymers and copolymers of cyclic ethers such as polyalkylene glycols, polyethylene oxide, polypropylene oxide or copolymers thereof with bisglycidyl ethers.

13. Polyacetals such as polyoxymethylene and those polyoxymethylenes which contain ethylene oxide as a comonomer; polyacetals modified with thermoplastic polyurethanes, acrylates or MBS.

14. Polyphenylene oxides and sulfides, and mixtures of polyphenylene oxides with styrene polymers or polyamides.

15. Polyurethanes derived from hydroxyl-terminated polyethers, polyesters or polybutadienes on the one hand and aliphatic or aromatic polyisocyanates on the other, as well as precursors thereof.

16. Polyamides and copolyamides derived from diamines and dicarboxylic acids and/or from aminocarboxylic acids or the corresponding lactams, for example polyamide 4, polyamide 6, polyamide 6/6, 6/10, 6/9, 6/12, 4/6, 12/12, polyamide 11, polyamide 12, aromatic polyamides starting from m-xylene diamine and adipic acid; polyamides prepared from hexamethylenediamine and isophthalic or/and terephthalic acid and with or without an elastomer as modifier, for example poly-2,4,4,-trimethylhexamethylene terephthalamide or poly-m-phenylene isophthalamide; and also block copolymers of the aforementioned polyamides with polyolefins, olefin copolymers, ionomers or chemically bonded or grafted elastomers; or with polyethers, e.g. with polyethylene glycol, polypropylene glycol or polytetramethylene glycol; as well as polyamides or copolyamides modified with EPDM or ABS; and polyamides condensed during processing (RIM polyamide systems).

17. Polyureas, polyimides, polyamide-imides, polyetherimids, polyesterimids, polyhydantoins and polybenzimidazoles.

18. Polyesters derived from dicarboxylic acids and diols and/or from hydroxycarboxylic acids or the corresponding lactones, for example polyethylene terephthalate, polybutylene terephthalate, poly-1,4-dimethylolcyclohexane terephthalate, polyalkylene naphthalate (PAN) and polyhydroxybenzoates, as well as block copolyether esters derived from hydroxyl-terminated polyethers; and also polyesters modified with polycarbonates or MBS.

19. Polycarbonates and polyester carbonates.

20. Polyketones.

21. Polysulfones, polyether sulfones and polyether ketones.

22. Crosslinked polymers derived from aldehydes on the one hand and phenols, ureas and melamines on the other hand, such as phenol/formaldehyde resins, urea/formaldehyde resins and melamine/formaldehyde resins.

23. Blends of the aforementioned polymers (polyblends), for example PP/EPDM, Polyamide/EPDM or ABS, PVC/EVA, PVC/ABS, PVC/MBS, PC/ABS, PBTP/ABS, PC/ASA, PC/PBT, PVC/CPE, PVC/acrylates, POM/thermoplastic PUR, PC/thermoplastic PUR, POM/acrylate, POM/MBS, PPO/HIPS, PPO/PA 6.6 and copolymers, PA/HDPE, PA/PP, PA/PPO, PBT/PC/ABS or PBT/PET/PC.

Especially useful polymer film materials for the purpose include polyethersulfon (PES), polyetheretherketone (PEEK), polycarbonate (PC), polyethyleneterephthalate (PET), polyethylenenaphthalene (PEN) polyamide and polyimide.

In suitable cases, the electrode itself may function as the substrate. Finally, all the elements of the photovoltaic cell can be connected to an external electronic circuit according to the state of the art to allow for the exploitation of the collected electrical energy.

Preparation of the cell generally may follow methods known in the art, see, for example, methods and materials described in EP-A-729190 or EP-A-831536, replacing the silicon film used therein as i-layer by the present photosensitive layer. The main photosensitive layer containing the present nanostructures may be obtained by techniques known in the art such as vapour deposition, PVD, CVD, plasma enhanced CVD, sputtering, precipitation, spin coating, drop coating etc. The technique used is not the determining factor for the final result; it is important that the nanoparticles or nanostructures be present in the final device, and not be solely an intermediate stage to a different product.

One embodiment of the invention is described below by way of example.

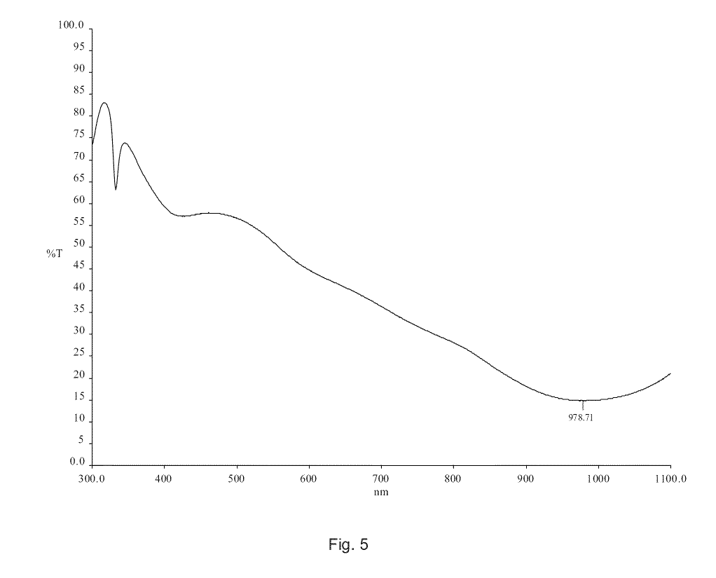

Silver metal nanoplatelets, of a triangular shape, are produced according to the procedure described in V. Bastys et al., Advanced Functional Materials 2006, 16, 766-773; a Xe lamp is used as a light source and a bandpass filter with a 540 nm transmittance maximum and a 77 nm full width at half maximum is used to select the desired photodirecting radiation. Irradiation is carried out until the color of the reaction medium is a deep blue and the spectrum of an extracted aliquot corresponds to that of FIG. 5. The nanoplatelets thus produced have a thickness of about 10 nm.

The silver nanoplatelets are washed of excess reagents by successive cycles of centrifugation and redispersion in water, ethanol and acetone. A dispersion in ethanol, containing enough nanoplatelets to cover about half the target surface, is drop-coated on a Czochralski (CZ) (100) n-type 1-Ω·cm 500-μm-thick, polished silicon wafer (c-Si wafer, previously etched in 0.5% diluted hydrofluoric acid). The solvent is allowed to evaporate, leaving behind a coating of Ag nanoplatelets.

The Ag-nanoplatelets-coated n-type c-Si wafer then is overlayed and underlayed with the other component layers of the photovoltaic cell via PECVD following the procedures described in Centurioni et al., Transactions on Electron Devices 2004, 51, 1818-1824, obtaining Inventive Example 1. 1×1 cm solar cells are fabricated using the structure Ag/ITO/p a-Si:H/nanoplatelets/n c-Si/n⁺μc-Si/Al. Another type of cell is obtained using the same procedure and tested as a reference sample (Comparative Example 1), without any buffer layer between p a-Si:H and n c-Si. The c-Si substrate is not texturized.

The plasma frequency for all the samples is 13.56 MHz. The Ag front grid and the Al back contact are evaporated. The indium tin oxide (ITO) film is deposited by RF (13.56 MHz) magnetron sputtering at 0.5 W/cm² power density, in a 0.021 mbar ultrapure Ar atmosphere, at 250° C. The electrical characteristics of the p layer (when deposited on Corning glass) are: dark conductivity 2×10⁻³ S/cm, and activation energy 0.25 eV. The 50-nm n⁺ mc-Si layer is deposited by PECVD, at low temperature, on the rear surface of the device, to reduce the contact resistance and form a back surface field (BSF) for photogenerated carriers. The a-Si:H layer thickness is 7 nm. The solar cell current density—voltage (J-V) characteristics under illumination are measured at 100 mW/cm AM1.5G irradiance.

The results of photoelectric measures are summarized in Table 1

TABLE 1

| | V_{oc} | J_{sc} | | | | |
|---|---|---|---|---|---|---|
| | (mV) | (mA/cm²) | FF | η | QE₉₈₀ | QE₅₀₀ |
| Inventive | 592 | 29 | 79 | 13.3 | 59 | 60 |
| Example 1 | | | | | | |
| Comparative | 554 | 28.2 | 77 | 12.9 | 43 | 60 |
| Example 1 | | | | | | |

where:

V_{oc}=open circuit voltage

J_{sc}=short circuit current

FF=fill factor

η=photoelectric efficiency (over the whole solar spectrum)

QE_{λ}=external quantum efficiency at nm (current measured per illumination photon)

1. A photovoltaic cell comprising at least one photosensitive layer containing nanoparticles or nanostructures and additionally comprising at least one n-doped charge transport layer and at least one p-doped charge transport layer per each photosensitive layer placed on each side of said photosensitive layer, characterized in that the nanoparticles or nanostructures are the main light absorbing element in the photosensitive layer,
the nanoparticles or nanostructures show metallic conductivity and absorb near infrared, visible and/or ultraviolet light through a surface plasmon or polaron mechanism,
the nanoparticles or nanostructures have at least one of their dimensions of size between 0.1 and 500 nm,
at least 50% by weight of said nanoparticles or nanostructures from all layers are contained in said photosensitive layer and
where the p-doped charge transport layers comprise a material selected from p-type amorphous silicon, amorphous silicon carbide, microcrystalline silicon, microcrystalline silicon carbide, carbon-containing microcrystalline silicon, a multilayer film of amorphous silicon carbides having different carbon contents and a multilayer film of amorphous silicon and amorphous carbon; and/or the n-doped charge transport layers comprise a material selected from n-type microcrystalline silicon, crystalline silicon, carbon-containing microcrystalline silicon, microcrystalline silicon carbide, amorphous silicon, amorphous silicon carbide and amorphous silicon germanium; or one or both charge transport layers consist of a wide band-gap semiconductor selected from TiO₂, ZnO₂ and SnO₂ which are suitably doped n- or p-.

2. A photovoltaic cell as of claim 1, whose photosensitive layer(s) absorb more than 50% of the light intensity over the solar spectrum between 1800 nm and 300 nm.

3. A photovoltaic cell as of claim 1 comprising between 1 and 100 photosensitive layers.

4. A photovoltaic cell as of claim 1 in which the nanoparticles or nanostructures of the at least one photosensitive layer have at least one of their dimensions of a size between 0.1 and 200 nm.

5. A photovoltaic cell as of claim 1 in which the nanoparticles or nanostructures of at least one photosensitive layer are made of a noble metal; an oxide of metallic conductivity; a bronze; a metal nitride, sulfide, selenide, boride or silicide; a compound of one or more metallic elements; or an alloy of one or more metallic elements with one or more elements of main groups III through VII.

6. A photovoltaic cell as of claim 1, containing 2 or more classes of nanoparticles or nanostructures of different average dimensions and/or different compositions.

7. A photovoltaic cell as of claim 1, which is a flexible cell on the basis of a polymer film substrate.

8. A photovoltaic cell as of claim 1, wherein at least 60% by weight of the nanoparticles or nanostructures have a resistivity of less than 100 Ωcm.

9. A photovoltaic cell as of claim 1, wherein the p-doped charge transport layers comprise microcrystalline silicon, microcrystalline silicon carbide or carbon-containing microcrystalline silicon.

10. A method for the preparation of a photovoltaic cell, which method comprises the step of concentrating nanoparticles or nanostructures showing metallic conductivity, absorbing near infrared, visible and/or ultraviolet light through a surface plasmon or polaron mechanism, and having at least one of their dimensions of size between 0.1 and 500 nm, in a photosensitive layer located between an n-doped charge transport layer and a p-doped charge transport layer, which charge transport layers contain little or none of said nanoparticles or nanostructures and
where the p-doped charge transport layer comprises a material selected from p-type amorphous silicon, amorphous silicon carbide, microcrystalline silicon, microcrystalline silicon carbide, carbon-containing microcrystalline silicon, a multilayer film of amorphous silicon carbides having different carbon contents and a multilayer film of amorphous silicon and amorphous carbon; and/or the n-doped charge transport layer comprises a material selected from n-type microcrystalline silicon, crystalline silicon, carbon-containing microcrystalline silicon, microcrystalline silicon carbide, amorphous silicon, amorphous silicon carbide and amorphous silicon germanium; or one or both charge transport layers consist of a wide band-gap semiconductor selected from TiO₂, ZnO₂ and SnO₂ which are suitably doped n- or p-.

11. A photovolataic cell as of claim 2, whose photosensitive layer(s) absorb all light over the solar spectrum between 1800 nm and 300 nm.

12. A photovoltaic cell as of claim 4 in which the nanoparticles or nanostructures have all of their dimensions of a size between 0.1 and 200 nm.

13. A photovoltaic cell as of claim 4 in which the nanoparticles or nanostructures have at least one of their dimensions of a size between 1 and 80 nm.

14. A photovoltaic cell as of claim 4 in which the nanoparticles or nanostructures have all of their dimensions of a size between 1 and 80 nm.

15. A photovoltaic cell as of claim 2, containing 2 or more classes of nanoparticles or nanostructures of different average dimensions and/or different compositions.

16. A photovoltaic cell as of claim 11, containing 2 or more classes of nanoparticles or nanostructures of different average dimensions and/or different compositions.

17. A method according to claim 10, where the nanoparticles or nanostructures are selected from 2 or more different classes of nanoparticles or nanostructures of different average dimensions and/or different compositions.

18. A photovoltaic cell as of claim 1, where the p-doped charge transport layer comprises a material selected from p-type amorphous silicon, amorphous silicon carbide, microcrystalline silicon, microcrystalline silicon carbide, carbon-containing microcrystalline silicon, a multilayer film of amorphous silicon carbides having different carbon contents and a multilayer film of amorphous silicon and amorphous carbon; and the n-doped charge transport layer comprises a material selected from n-type microcrystalline silicon, crystalline silicon, carbon-containing microcrystalline silicon, microcrystalline silicon carbide, amorphous silicon, amorphous silicon carbide and amorphous silicon germanium.

19. A photovoltaic cell as of claim 1, where the p-doped charge transport layer comprises a material selected from p-type amorphous silicon, amorphous silicon carbide, microcrystalline silicon, microcrystalline silicon carbide, carbon-containing microcrystalline silicon, a multilayer film of amorphous silicon carbides having different carbon contents and a multilayer film of amorphous silicon and amorphous carbon.

20. A photovoltaic cell as of claim 1, where the n-doped charge transport layer comprises a material selected from n-type microcrystalline silicon, crystalline silicon, carbon-containing microcrystalline silicon, microcrystalline silicon carbide, amorphous silicon, amorphous silicon carbide and amorphous silicon germanium.

21. A photovoltaic cell as of claim 1, where one or both charge transport layers consist of wide band-gap semiconductor selected from TiO₂, ZnO₂ and SnO₂ which are suitably doped n- or p-.
